(19) United States
(12) Patent Application Publication
(10) Pub. No.: US 2002/0088970 A1
(43) Pub. Date: Jul. 11, 2002

(54) Self-assembled quantum structures and method for fabricating same

(75) Inventors: Zhiyi Yu, Gilbert, AZ (US); Ravindranath Droopad, Chandler, AZ (US); Jerald A. Hallmark, Gilbert, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Motorola, Inc.

(21) Appl. No.: 09/755,341

(22) Filed: Jan. 5, 2001

(51) Int. Cl. H01L 29/06; H01L 29/12; H01L 29/15; H01L 21/31; H01L 21/469

(52) U.S. Cl. 257/12; 257/43; 438/785; 438/962

(57) ABSTRACT

A quantum structure (300) having photo-catalytic properties includes a monocrystalline substrate (302) and a monocrystalline metal oxide layer (308) formed of a material comprising titanium and oxygen and epitaxially grown overlying the substrate. The quantum structure further includes self-assembled quantum dots (312) disposed on the monocrystalline metal oxide layer and formed of a material comprising copper and oxygen.

### FIELD OF THE INVENTION

This invention relates generally to semiconductor structures and devices and to a method for their fabrication, and more specifically to quantum structures that have photo-catalytic properties and that are fabricated on a monocrystalline material.

### BACKGROUND OF THE INVENTION

Various metal oxides, such as Cu₂O, TiO₂, SrTiO₃ and the like, exhibit desirable characteristics such as photo-catalysis properties. Such oxides may be included or used in connection with quantum structures, particularly self-assembled quantum dots, that take advantage of these characteristics.

Because of these desirable characteristics of various metal oxide materials, and because of their present generally high cost and low availability in bulk form, for many years attempts have been made to grow thin films of the desired metal oxide materials on a foreign substrate. To achieve optimal characteristics of metal oxide material, however, a monocrystalline film of high crystalline quality is desired. Attempts have been made, for example, to grow layers of a monocrystalline metal oxide material on substrates such as silicon. The attempts have generally been unsuccessful because the formation of amorphous SiO₂ layers prevent epitaxial growth of high quality metal oxides. Metal oxides of higher quality have been grown over oxide substrates such as bulk strontium titanate. However, metal oxides grown over oxide substrates are often expensive because, in part, the oxide substrate is small.

If a large area thin film of high quality monocrystalline metal oxide material was available at low cost, a variety of semiconductor devices, such as photo-catalytic devices, could advantageously be fabricated at a low cost compared to the cost of fabricating such devices on a bulk wafer of the metal oxide material or in an epitaxial film of such material on a bulk wafer of oxide material. In addition, if a thin film of high quality monocrystalline metal oxide material could be realized on a bulk wafer such as a silicon wafer, an integrated device structure could be achieved that took advantage of the best properties of both the silicon and the metal oxide material.

Accordingly, a need exists for a microelectronic structure that provides a high quality monocrystalline metal oxide film over another monocrystalline material and a process for making such a structure.

Attempts have been made to fabricate self-assembled quantum dots on bulk metal oxides, such as SrTiO₃ or TiO₂. Quantum dots are regions in which the charge carriers are surrounded in all directions by potential barriers and have quantized energy levels. Quantum dots provide advantages in optoelectronics because they respond very efficiently to particular wavelengths of light. However, prior art techniques have not been able to conveniently fabricate quantum dots on thin film metal oxide photo-catalytic elements on a monocrystalline substrate, and thereby lack the capability of monolithic integration with circuits formed in the substrate.

Accordingly, a need exists for a quantum structure that provides a high quality photo-catalytic element over a monocrystalline material and for a process for making such a structure.

### BRIEF DESCRIPTION OF THE DRAWINGS

The present invention is illustrated by way of example and not limitation in the accompanying figures, in which like references indicate similar elements, and in which:

FIGS. 1-3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9A-9D illustrate schematically, in cross-section, the formation of a device structure in accordance with another embodiment of the invention;

FIGS. 10-10D illustrate a probable molecular bonding structure of the device structures illustrated in FIGS. 9A-9D;

FIGS. 11-14 illustrate schematically, in cross-section, the formation of a device structure in accordance with still another embodiment of the invention;

FIGS. 15-17 illustrate schematically, in cross-section, the formation of yet another embodiment of a device structure in accordance with the invention;

FIGS. 18-19 illustrate schematically, in cross-section, an exemplary embodiment of a quantum structure fabricated on a semiconductor substrate according to the present invention; and

FIGS. 20-21 illustrate schematically, in cross-section, another exemplary embodiment of a quantum structure fabricated on a semiconductor substrate according to the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE INVENTION

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table, and preferably a material from Group IVA. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26, which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure matched to the substrate and to the subsequently applied monocrystalline material layer. Materials that are suitable for the accommodating buffer layer include metal oxides such as the alkaline earth metal oxides, alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitride may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may include SrTiO₃, SrBaTiO₃, BaTiO₃, CaTiO₃, MgTiO₃ and TiO₂, having a thickness in the range of about 1 nm to about 100 nm.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

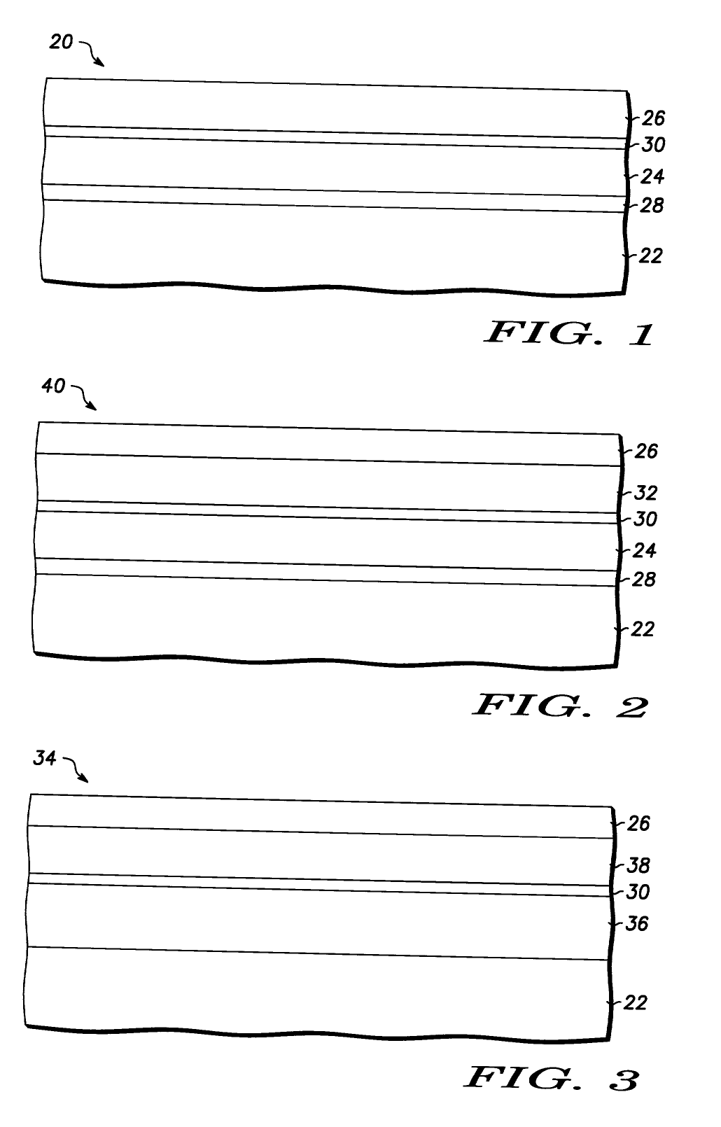

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr₂Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the compound semiconductor layer from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1-2 nm.

In accordance with this embodiment of the invention, monocrystalline material layer 26 is a layer of SrTiO₃ having a thickness of about 1 nm to about 100 nm and preferably a thickness of about 10 nm to 20 nm. The thickness generally depends on the application for which the layer is being prepared.

### EXAMPLE 2

In accordance with another embodiment of the invention, a structure is provided that is suitable for the growth of an epitaxial film of photo-catalytic material overlying a conductive material as illustrated in FIG. 2. The substrate is preferably a silicon wafer as described above. A suitable accommodating buffer layer is SrₓBa₁₋ₓTiO₃, where x ranges from 0 to 1, having a thickness of about 2-100 nm and preferably a thickness of about 5-15 nm. The conducting oxide can be (La, Sr) CoO₃, having a thickness of about 2 to about 200 nm and preferably a thickness of about 10 to about 100 nm. A layer of photo-catalytic material may be deposited overlying the conducting oxide layer and may include TiO₂, having a thickness of about 1 nm to 100 nm and preferably a thickness of about 10 to about 20 nm.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkali earth metals or combinations of alkali earth metals in an MBE apparatus. In the case where strontium is used, the substrate is then heated to a temperature of about 850° C. to cause the strontium to react with the native silicon oxide layer. The strontium serves to reduce the silicon oxide to leave a silicon oxide-free surface. The resultant surface, which exhibits an ordered 2x1 structure, includes strontium, oxygen, and silicon. The ordered 2x1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkali earth metal oxide, such as strontium oxide, strontium barium oxide, or barium oxide, onto the substrate surface by MBE at a low temperature and by subsequently heating the structure to a temperature of about 850° C. At this temperature a solid state reaction takes place between the strontium oxide and the native silicon oxide causing the reduction of the native silicon oxide and leaving an ordered 2x1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stochiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered monocrystal with the crystalline orientation rotated by 45° with respect to the ordered 2x1 crystalline structure of the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate surface is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

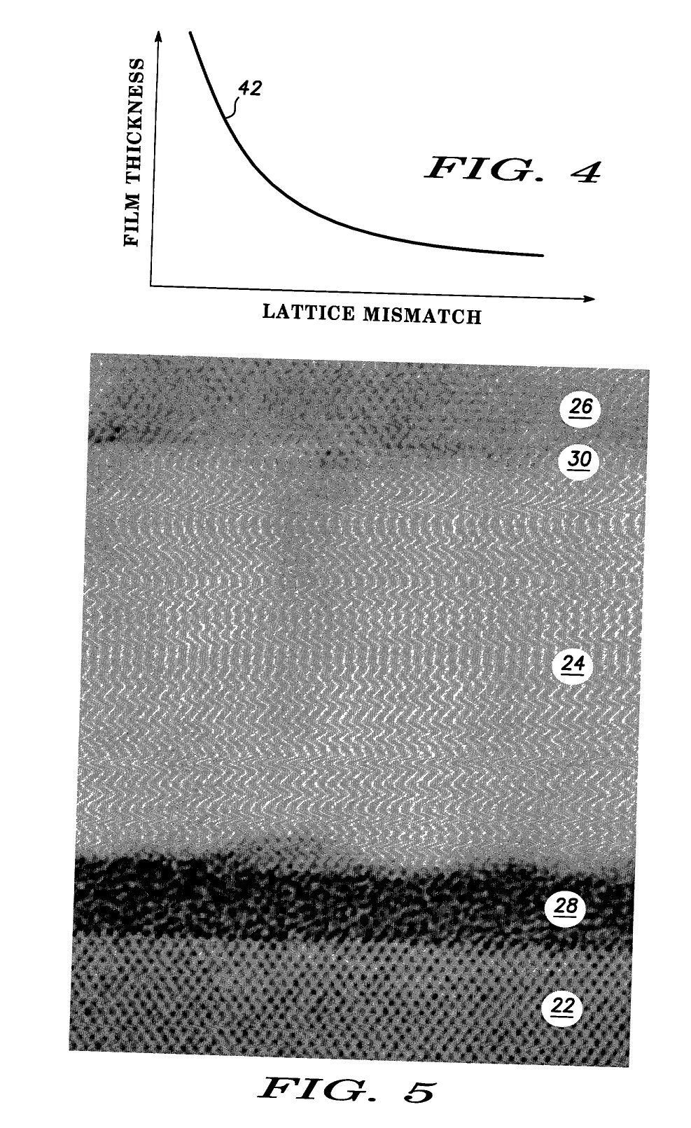

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

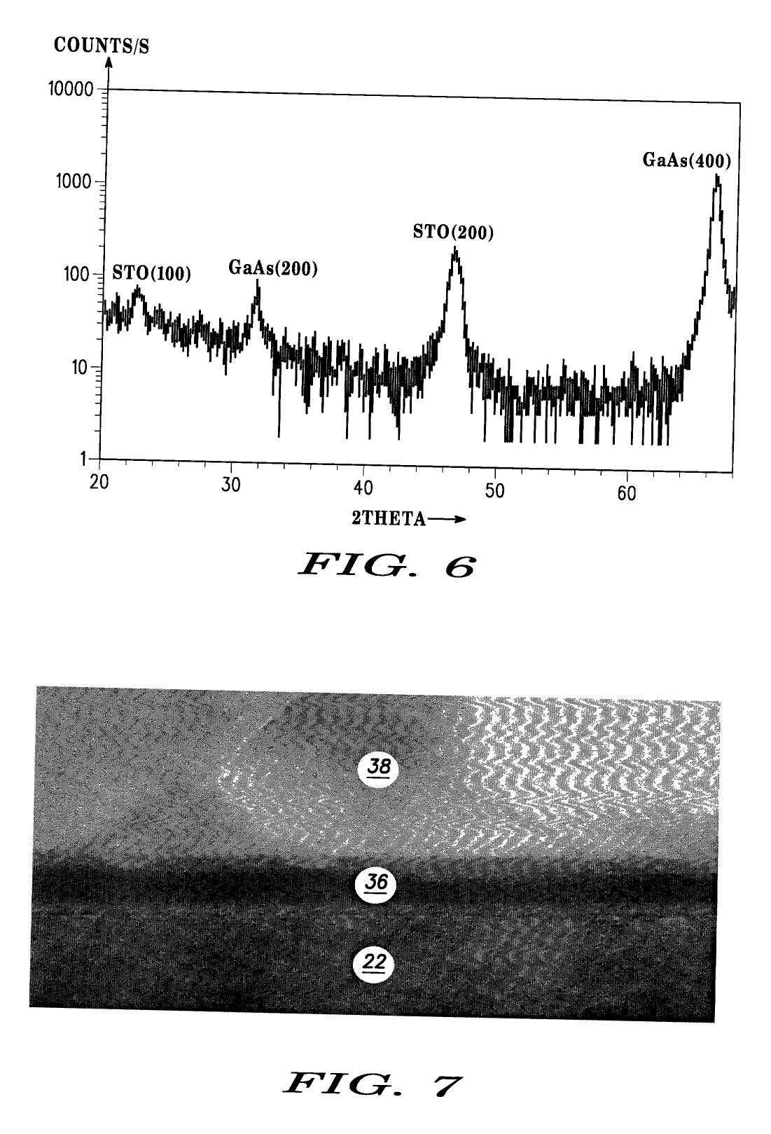

FIG. 6 illustrates an x-ray diffraction spectrum taken on a structure including monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The buffer layer is formed overlying the template layer before the deposition of the monocrystalline material layer. If the buffer layer is a monocrystalline material layer comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution Transmission Electron Micrograph (TEM) of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal oxides, alkaline earth metal titanates, zirconates, hafnates, tantalates, vanadates, ruthenates, and niobates, perovskite oxides such as alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising indium gallium arsenide, indium aluminum arsenide, or indium phosphide.

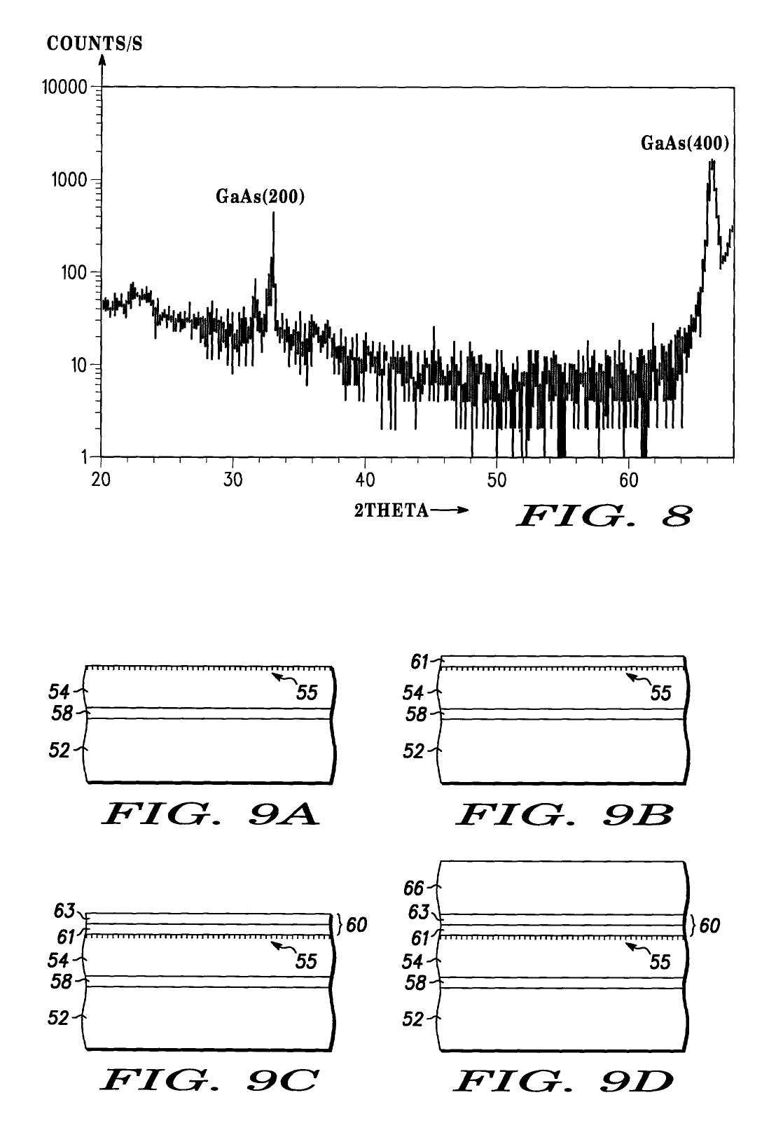

The formation of a device structure in accordance with another embodiment of the invention is illustrated schematically in cross-section in FIGS. 9A-9D. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9A-9D utilizes a template that includes a surfactant to facilitate layer-by-layer monocrystalline material growth.

Turning now to FIG. 9A, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to approximately 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9A by hatched line 55 which is followed by the addition of a template layer 60 which includes a surfactant layer 61 and capping layer 63 as illustrated in FIGS. 9B and 9C. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 9B by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a halogen such as arsenic, for example, to form capping layer 63 as illustrated in FIG. 9C. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 9D.

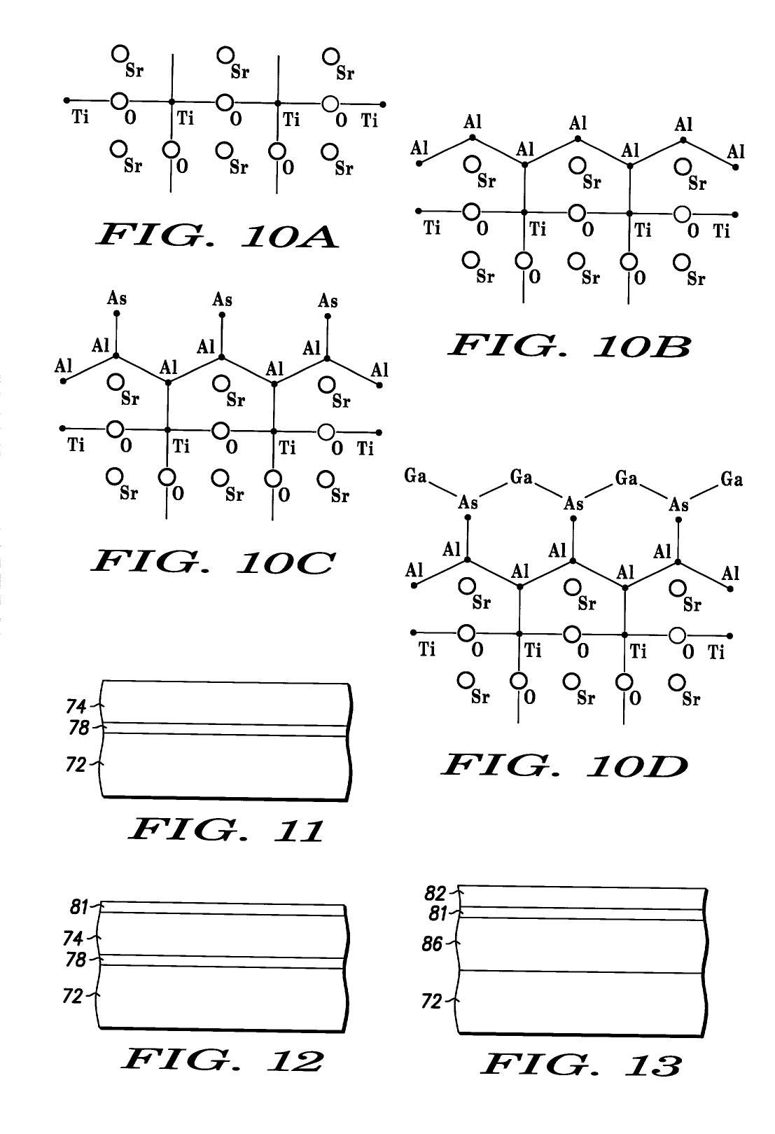

FIGS. 10A-10D illustrate possible molecular bond structures for a specific example of a compound semiconductor structure formed in accordance with the embodiment of the invention illustrated in FIGS. 9A-9D. More specifically, FIGS. 10A-10D illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 9B-9D, to increase the surface energy of the monocrystalline oxide layer 54 and also to shift the crystalline structure of the template to a diamond-like structure that is in compliance with the original GaAs layer.

FIG. 10A illustrates the molecular bond structure of a strontium terminated surface of a strontium titanate monocrystalline oxide layer. An aluminum surfactant layer is deposited on top of the strontium terminated surface and bonds with that surface as illustrated in FIG. 10B, which reacts to form a capping layer comprising a monolayer of Al₂Sr having the molecular bond structure illustrated in FIG. 10B which forms a diamond-like structure with an sp³ hybrid terminated surface that is compliant with compound semiconductors such as GaAs. The structure is then exposed to As to form a layer of AlAs as shown in FIG. 10C. GaAs is then deposited to complete the molecular bond structure illustrated in FIG. 10D which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 24 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising germanium (Ge), for example, to form high efficiency photocells.

Turning now to FIGS. 11-14, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 11. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 12 with a thickness of a few hundred Angstroms but preferably with a thickness of about 50 angstroms. Monocrystalline oxide layer 74 preferably has a thickness of about 20 to 100 angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 13. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosized to form a silicate layer which adsorbs the strain between the layers. Moreover, unlike past use of a SiC substrate, this embodiment of the invention is not limited by wafer size which is usually less than 2 inches in diameter for SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

FIGS. 15-17 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 15 includes a monocrystalline substrate 102, an amorphous interface layer 108 and an accommodating buffer layer 104. Amorphous intermediate layer 108 is grown on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2 but preferably comprises a monocrystalline oxide material such as a monocrystalline layer of Sr_{z}Ba_{1-z}TiO₃ where z ranges from 0 to 1. Substrate 102 is preferably silicon but may also comprise any of those materials previously described with reference to substrate 22 in FIGS. 1-3.

A template layer 130 is deposited over accommodating buffer layer 104 as illustrated in FIG. 16 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂

A monocrystalline material layer 126 is epitaxially grown over template layer 130 to achieve the final structure illustrated in FIG. 17. As a specific example, an SrAl₂ layer may be used as template layer 130 and an appropriate monocrystalline material layer 126 such as a compound semiconductor material GaAs is grown over the SrAl₂. The Al-Ti (from the accommodating buffer layer of layer of Sr_{z}Ba_{1-z}TiO₃ where z ranges from 0 to 1) bond is mostly metallic while the Al-As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an Sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

Another embodiment of the present invention includes use of the semiconductor structures described above in quantum structures, particularly structures employing self-assembled quantum dots. An advantage of self-assembled quantum dots is that they respond very efficiently to particular wavelengths of light. When fabricated from material comprising copper and oxygen on crystalline material comprising titanium and oxygen, such structures take advantage of the photo-catalytic properties of both materials. Cu₂O, in particular, responds to a large range of solar radiation wavelengths. These photo-catalytic properties can be used in applications such as splitting H₂O molecules to generate H₂ fuel which can be used as an energy source in mobile devices. When fabricated on Si substrate, quantum structures comprising quantum dots also may provide the advantages of larger wafer size and the potential integration with circuits fabricated in the Si substrate.

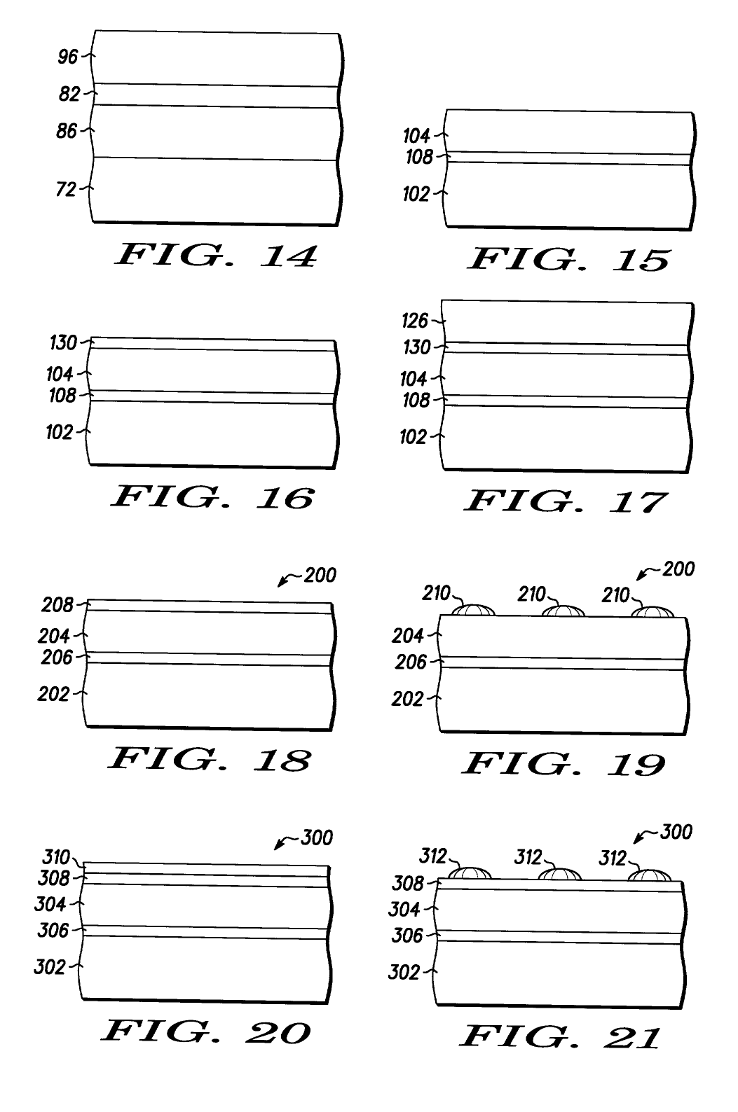

FIG. 18 illustrates in cross-section an exemplary embodiment of a self-assembled quantum structure 200 in accordance with the present invention. To fabricate quantum structure 200, a monocrystalline semiconductor substrate 202 functions as the starting material. Substrate 202, in accordance with an embodiment of the invention, is a monocrystalline semiconductor or compound semiconductor wafer, preferably of large diameter. The substrate 202 may be of, for example, a material from Group IV of the periodic table, and preferably a material from Group IVA. Examples of Group IV semiconductor materials include silicon, germanium, mixed silicon and germanium, mixed silicon and carbon, mixed silicon, germanium and carbon, and the like. Alternatively, substrate 202 may be selected from any of the Group IIIA and VA elements (III-V semiconductor compounds), such as GaAs. Preferably substrate 202 is a wafer containing silicon or germanium, and most preferably is a high quality monocrystalline Si (001) wafer as used in the semiconductor industry.

A metal oxide layer 204 is then grown epitaxially over substrate 202 and an amorphous intermediate layer 206 may be formed between substrate 202 and metal oxide layer 204 by the oxidation of substrate 202 during the growth of metal oxide layer 204. Metal oxide layer 204 is fabricated from material containing titanium and oxygen and is preferably formed of material containing at least one of SrTiO₃, BaTiO₃, CaTiO₃, MgTiO₃ or TiO₂. To enhance absorption by metal oxide layer 204 of visible light and broaden the range of wavelengths to which metal oxide layer 204 responds, metal oxide layer 204 may be doped with Fe₂O₃, RuO₂ or similar materials without compromising the crystal structure of layer 204. The thickness of metal oxide layer 204 is in the range of from approximately 1 nm to approximately 100 nm, and is preferably in the range of from approximately 10 nm to approximately 20 nm.

A copper oxide layer 208 having a copper:oxygen ratio of 2:1 is then deposited on the metal oxide layer. Copper oxide layer 208 may be any suitable material comprising copper and oxygen in a 2-to-1 ratio, but is preferably Cu₂O. The copper oxide layer 208 and metal oxide layer 204 are selected to have crystal lattices that differ by at least 5%. Due to the large lattice mismatch between the copper oxide layer and the metal oxide layer, the copper oxide layer grows epitaxially on the surface of the metal oxide layer until a critical thickness, typically of approximately 3-5 nm, is reached, at which point three-dimensional quantum dots begin to form. As processing continues, the copper oxide layer initially formed on the metal oxide layer evolves into self-assembled quantum dots 210, exposing the metal oxide surface in areas between the quantum dots, as shown in FIG. 19.

FIG. 20 illustrates in cross section another exemplary embodiment of a self-assembled quantum structure 300. To fabricate quantum structure 300, a monocrystalline semiconductor substrate 302, which may be a semiconductor or compound semiconductor wafer such as that comprising layer 202 with reference to FIG. 18, functions as the starting material. An accommodating buffer layer 304 is then grown epitaxially over substrate 302 and an amorphous intermediate layer 306 may be formed between substrate 302 and buffer layer 304 by the oxidation of substrate 302 during the growth of buffer layer 304. Buffer layer 304 may be comprised of a monocrystalline oxide or nitride material such as that comprising layers 24, 54, 74 and 104 with reference to FIGS. 1, 9, 11 and 15, respectively. In accordance with one embodiment of the invention (not illustrated), a layer may comprise material from amorphous oxide layer 306 and material from buffer layer 304, which is formed by annealing amorphous layer 306 and buffer layer 304, forming a layer such as layer 36 described with reference to FIG. 3 and layer 86 described with reference to FIG. 13.

A monocrystalline metal oxide layer 308 is then grown epitaxially over buffer layer 304. Metal oxide layer 308 may be comprised of material such as that comprising layer 204 with reference to FIG. 18. Buffer layer 304 serves to provide a lattice compensation between amorphous layer 306 and metal oxide layer 308. The thickness of metal oxide layer 308 is in the range from approximately 1 nm to approximately 100 nm, and is preferably in the range of from approximately 10 nm to approximately 20 nm.

A copper oxide layer 310 having a copper:oxygen ratio of 2:1 is then deposited on the metal oxide layer. Copper oxide layer 310 may be comprised of material such as that comprising layer 208 with reference to FIG. 18. As with copper oxide layer 208 and metal oxide layer 204 of quantum structure 200, copper oxide layer 310 and metal oxide layer 308 are selected to have crystal lattices that differ by at least 5%. Due to the large mismatch between the copper oxide layer and the metal oxide layer, the copper oxide layer 310 grows epitaxially on the surface of the metal side layer 308 until a critical thickness of approximately 3-5 nm is reached, at which point three-dimensional quantum dots begin to form. As processing continues, the copper oxide layer initially formed on the metal oxide layer evolves into self-assembled quantum dots 312, exposing the metal oxide surface in areas between the quantum dots, as shown in FIG. 21.

Although not illustrated in FIGS. 20-21, either of the structures illustrated in these figures may include an additional buffer layer between the substrate and the accommodating buffer layer to provide lattice compensation between the substrate and the buffer layer. Further, although not illustrated in FIGS. 18-21, any of these structures may include a template layer formed of materials such as those comprising layer 30 with reference to FIGS. 1-3, layer 60 with reference to FIGS. 9C-9D, layer 82 with reference to FIGS. 13-14, and layer 130 with reference to FIGS. 16-17.

Quantum structure 200, quantum structure 300 or any other quantum structure fabricated according to an embodiment of the present invention may be coupled to a CMOS device (not shown) via an electrical connection. The CMOS device may comprise a device such as a MOSFET which is formed by conventional semiconductor processing as is well known and widely practiced in the semiconductor industry. At least a portion of the CMOS device may be formed in the substrate or, alternatively, the CMOS device may be formed in a separate substrate and coupled to quantum structure 200 by conventional methods.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of the present invention.

Benefits, other advantages, and solutions to problems have been described above with regard to specific embodiments. However, the benefits, advantages, solutions to problems, and any element(s) that may cause any benefit, advantage, solution to occur or become more pronounced are not to be constructed as critical, required, or essential features or elements of any or all of the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A quantum structure having photo-catalytic properties comprising:
a monocrystalline substrate;
a monocrystalline metal oxide layer formed of a material comprising titanium and oxygen and epitaxially grown overlying the substrate; and
self-assembled quantum dots disposed on the monocrystalline metal oxide layer and formed of a material comprising copper and oxygen.

2. The quantum structure of claim 1, further comprising an amorphous oxide layer underlying the monocrystalline metal oxide layer.

3. The quantum structure of claim 1, further comprising an integrated circuit, wherein at least a portion of the integrated circuit is formed in the substrate and is electrically coupled to the quantum structure.

4. The quantum structure of claim 1, wherein the substrate comprises silicon.

5. The quantum structure of claim 1, wherein the monocrystalline metal oxide layer is formed of a material selected from the group comprising SrTiO₃, BaTiO₃, CaTiO₃, MgTiO₃, TiO₂ and SrₓBa₁₋ₓTiO₃, where x ranges from 0 to approximately 1.

6. The quantum structure of claim 1, wherein the quantum dots comprise Cu₂O.

7. The quantum structure of claim 1, further comprising an accommodating buffer layer epitaxially grown overlying the substrate and underlying the monocrystalline metal oxide layer.

8. The quantum structure of claim 7, wherein the accommodating buffer layer comprises an oxide selected from the group consisting of alkaline earth metal oxides, alkaline earth metal titanates, alkaline earth metal zirconates, alkaline earth metal hafnates, alkaline earth metal tantalates, alkaline earth metal ruthenates, alkaline earth metal niobates and perovskite oxides.

9. The quantum structure of claim 7, wherein the accommodating buffer layer comprises Sr_{z}Ba_{l-z}TiO₃, where z ranges from 0 to approximately 1.

10. The quantum structure of claim 7, further comprising an additional buffer layer positioned between the accommodating buffer layer and the monocrystalline metal oxide layer.

11. The quantum structure of claim 7, further comprising a template layer positioned between the accommodating buffer layer and the monocrystalline metal oxide layer.

12. The quantum structure of claim 11, wherein the template layer comprises a Zintl-type phase material.

13. The quantum structure of claim 12, wherein the Zintl-type phase material comprises at least one of SrAl₂, (MgCaYb) Ga₂, (Ca, Sr, Eu, Yb) In₂, BaGe₂As, and SrSn₂As₂.

14. The quantum structure of claim 11, wherein the template layer comprises a surfactant material.

15. The quantum structure of claim 14, wherein the surfactant material comprises at least one of Al, In, and Ga.

16. The quantum structure of claim 14, wherein the template layer further comprises a capping layer.

17. The quantum structure of claim 16, wherein the capping layer is formed by exposing the surfactant material to a cap-inducing material.

18. The quantum structure of claim 17, wherein the cap-inducing material comprises at least one of As, P, Sb and N.

19. The quantum structure of claim 11, wherein the template layer comprises a silicon layer.

20. The quantum structure of claim 19, further comprising a capping layer.

21. The quantum structure of claim 20, wherein the capping layer is formed by rapid thermal annealing in the presence of a carbon source.

22. The quantum structure of claim 7, wherein the accommodating buffer layer comprises an oxide formed as a monocrystalline oxide and subsequently heat treated to convert the monocrystalline oxide to an amorphous oxide.

23. The quantum structure of claim 22, wherein the monocrystalline substrate is characterized by a first lattice constant and the monocrystalline metal oxide layer is characterized by a second lattice constant different than the first lattice constant.

24. The quantum structure of claim 23, wherein the monocrystalline oxide is characterized by a third lattice constant different than the second lattice constant.

25. The quantum structure of claim 22, wherein the monocrystalline substrate is characterized by a first crystalline orientation and the monocrystalline oxide is characterized by a second crystalline orientation, and wherein the second crystalline orientation is rotated with respect to the first crystalline orientation.

26. The quantum structure of claim 1, wherein the monocrystalline metal oxide layer has a thickness in the range of about 1 nm to about 100 nm.

27. The quantum structure of claim 1, wherein the monocrystalline metal oxide layer is doped with at least one of Fe₂O₃ and RuO₂.

28. A process for fabricating a quantum structure having photo-catalytic properties comprising:
providing a monocrystalline substrate;
epitaxially growing a monocrystalline metal oxide layer overlying the substrate, wherein the metal oxide layer is formed of a material comprising titanium and oxygen;
growing quantum dots on the metal oxide layer, wherein the quantum dots are formed of a material comprising copper and oxygen.

29. The process of claim 28, further comprising forming at least a portion of an integrated circuit in the substrate and electrically coupling the quantum structure to the integrated circuit.

30. The process of claim 28, further comprising forming an amorphous oxide layer underlying the metal oxide layer during the step of epitaxially growing the metal oxide layer.

31. The process of claim 28, wherein providing a monocrystalline substrate comprises providing a substrate formed of silicon.

32. The process of claim 28, wherein epitaxially growing a metal oxide layer comprises epitaxially growing a metal oxide layer formed of a material selected from the group comprising SrTiO₃, BaTiO₃, CaTiO₃, MgTiO₃, TiO₂ and SrₓBa₁₋ₓTiO₃.

33. The process of claim 28, wherein growing quantum dots comprises growing quantum dots formed of Cu₂O.

34. The process of claim 28, further comprising epitaxially growing an accommodating buffer layer overlying the substrate and underlying the metal oxide layer.

35. The process of claim 34, wherein epitaxially growing an accommodating buffer layer comprises epitaxially growing a monocrystalline oxide layer comprising an oxide selected from the group consisting of alkaline earth metal oxides, alkaline earth metal titanates, alkaline earth metal zirconates, alkaline earth metal hafnates, alkaline earth metal tantalates, alkaline earth metal ruthenates, alkali earth metal niobates and perovskite oxides.

36. The process of claim 35, further comprising annealing the monocrystalline oxide layer to convert the monocrystalline oxide layer to an amorphous oxide layer, the annealing being carried out after at least the epitaxially growing the metal oxide layer.

37. The process of claim 35, wherein epitaxially growing a monocrystalline oxide layer comprises growing a monocrystalline oxide layer comprising Sr_{z}Ba_{l-z}TiO₃, where z ranges from 0 to approximately 1.

38. The process of claim 28, wherein each of the steps of epitaxially growing comprises the step of epitaxially growing by a process selected from the group consisting of MBE, MOCVD, MEE, CVD, PVD, PLD, CSD and ALE.

39. The process of claim 34, further comprising epitaxially growing an additional buffer layer overlying the accommodating buffer layer and underlying the metal oxide layer.

40. The process of claim 34, further comprising forming a template layer overlying the accommodating buffer layer and underlying the metal oxide layer.

41. The process of claim 40, wherein forming a template layer comprises forming a template layer comprising a Zintl-type phase material.

42. The process of claim 41, wherein forming a template layer of Zintl-type phase material comprises forming a template layer of Zintl-type phase material selected from the group comprising SrAl₂, (Mg, Ca, Yb) Ga₂, (Ca, Sr, Eu, Yb) In₂, BaGe₂As, and SrSn₂As₂.

43. The process of claim 40, wherein forming a template layer comprises forming a template layer comprising surfactant material.

44. The process of claim 43, wherein forming a template layer comprising surfactant material comprises forming a template layer comprising surfactant material formed of at least one of Al, In and Ga.

45. The process of claim 43, wherein forming a template layer comprises forming a template layer having a capping layer.

46. The process of claim 45, wherein forming a template layer having a capping layer comprises exposing the surfactant material to a cap-inducing material.

47. The process of claim 46, wherein exposing the surfactant material to a cap-inducing material comprises exposing the surfactant material to at least one of As, P, Sb and N.

48. The process of claim 40, wherein forming a template layer comprises forming a silicon layer.

49. The process of claim 48, further comprising forming a capping layer by rapid thermal annealing in the presence of a carbon source.

50. The process of claim 34, wherein said epitaxially growing an accommodating buffer layer comprises growing a monocrystalline oxide layer and subsequently heating the monocrystalline oxide layer to convert the monocrystalline oxide layer to an amorphous oxide layer.

51. The process of claim 50, wherein providing a monocrystalline substrate comprises providing a monocrystalline substrate characterized by a first lattice constant and, wherein epitaxially growing a metal oxide layer comprises growing a metal oxide layer characterized by a second lattice constant which is different than the first lattice constant.

52. The process of claim 51, wherein growing a monocrystalline oxide layer comprises growing a monocrystalline oxide layer characterized by a third lattice constant which is different than the second lattice constant.

53. The process of claim 50, wherein the step of providing a monocrystalline substrate comprises providing a monocrystalline substrate characterized by a first crystalline orientation and the step of growing a monocrystalline oxide layer comprises growing a monocrystalline oxide layer characterized by a second crystalline orientation and wherein the second crystalline orientation is rotated with respect to the first crystalline orientation.

54. The process of claim 28, further comprising doping the monocrystalline metal oxide layer with at least one of Fe₂O₃ and RuO₃.

55. A quantum structure having photo-catalytic properties comprising:
a monocrystalline substrate;
a monocrystalline metal oxide layer formed of a material comprising titanium and oxygen and characterized by a first lattice constant, wherein said monocrystalline metal oxide layer is epitaxially grown overlying the substrate; and
quantum dots disposed on the monocrystalline metal oxide layer and formed of a material characterized by a second lattice constant, wherein the first lattice constant and the second lattice constant differ by at least 5%.

56. The quantum structure of claim 55, further comprising an amorphous oxide layer underlying the monocrystalline metal oxide layer.

57. The quantum structure of claim 55, further comprising an integrated circuit, wherein at least a portion of the integrated circuit is formed in the substrate and is electrically coupled to the quantum structure.

58. The quantum structure of claim 55, wherein the substrate comprises silicon.

59. The quantum structure of claim 55, wherein the monocrystalline metal oxide layer is formed of a material selected from the group comprising SrTiO₃, BaTiO₃, CaTiO₃, MgTiO₃ TiO₂ and SrₓBa₁₋ₓTiO₃, where x ranges from 0 to approximately 1.

60. The quantum structure of claim 55, wherein the quantum dots comprise Cu₂O.

61. The quantum structure of claim 55, further comprising an accommodating buffer layer epitaxially grown overlying the substrate and underlying the monocrystalline metal oxide layer.

62. The quantum structure of claim 61, wherein the accommodating buffer layer comprises an oxide selected from the group consisting of alkaline earth metal oxides, alkaline earth metal titanates, alkaline earth metal zirconates, alkaline earth metal hafnates, alkaline earth metal tantalates, alkaline earth metal ruthenates, alkaline earth metal niobates and perovskite oxides.

63. The quantum structure of claim 61, wherein the accommodating buffer layer comprises Sr_{z}Ba_{l-z}TiO₃, where z ranges from 0 to approximately 1.

64. The quantum structure of claim 61, further comprising an additional buffer layer positioned between the accommodating buffer layer and the monocrystalline metal oxide layer.

65. The quantum structure of claim 61, further comprising a template layer positioned between the accommodating buffer layer and the monocrystalline metal oxide layer.

66. The quantum structure of claim 55, wherein the monocrystalline metal oxide layer is doped with at least one of Fe₂O₃ and RuO₂.
